(19) United States
(12) Patent Application Publication
(10) Pub. No.: US 2026/0213736 A1
(43) Pub. Date: Jul. 23, 2026

(54) VOLTAGE-CONTROLLED OSCILLATOR CIRCUITS

(71) Applicant: Cirrus Logic International Semiconductor Ltd., Edinburgh (GB)

(72) Inventors: John P. LESSO, Edinburgh (GB); James T. DEAS, Edinburgh (GB)

(73) Assignee: Cirrus Logic International Semiconductor Ltd., Edinburgh (GB)

(21) Appl. No.: 19/427,345

(22) Filed: Dec. 19, 2025

Related U.S. Application Data
(63) Continuation-in-part of application No. 19/027,617, filed on Jan. 17, 2025.

(51) Int. Cl. H03K 3/03; H03K 5/00; H03K 5/01

(52) U.S. Cl. CPC H03K 3/0315; H03K 2005/00078; H03K 5/01

(57) ABSTRACT

The present application relates to voltage-controlled oscillators (VCOs), in particular to VCOs suitable for implementation in compound semiconductor material and to the use of such VCOs. The VCO has an input node for receiving an input control voltage and an odd plurality of delay elements connected in a ring arrangement. Each delay element is connected between first and second defined voltages and comprises a depletion mode high-electron mobility transistor connected between the first defined voltage and an output of the delay element. The gate of the depletion mode high-electron mobility transistor is driven by the input control voltage and the gate of the enhancement mode high-electron mobility transistor is driven by the output of a preceding delay element.

### TECHNICAL FIELD

The field of representative embodiments of this disclosure relates to methods, apparatus and/or implementations concerning or relating to oscillator circuits, especially to voltage-controlled oscillator circuits implemented in a compound semiconductor material system, such as Gallium Nitride (GaN).

### BACKGROUND

Integrated circuits have typically been implemented using a single-element silicon materials system with appropriate doping, for instance using CMOS (complementary-metal-oxide-semiconductor) processing. For some applications, however, the use of compound semiconductor materials may have advantages. For example, the properties of GaN can make it advantageous for use in some applications, for instance due to the fast switching speed, high electron mobility and relatively high-breakdown voltages of GaN transistor devices. The use of GaN is thus increasingly being considered for some applications, for instance as an output stage of a DC/DC converter or switching driver or class-D type amplifier or the like, particularly for high power and/or high voltage applications. However, the properties of GaN can pose challenges for integrating other circuitry, into a GaN based integrated circuit. For instance, as will be understood by one skilled in the art, whilst n-channel devices can be readily formed in GaN, commercially available fabrication techniques are generally not able to form effective p-channel devices and thus complementary integrated circuits designs are generally not available for use in GaN circuits. For at least some applications, it may therefore be typical to implement some circuitry in GaN, e.g. a switching output stage, but then implement other circuitry, e.g. for sensing and/or control, on a separate single-element silicon IC. In some use cases, it would be desirable to be able to implement more circuit components in GaN to be formed as part of a GaN integrated circuit.

One component which is often used in integrated circuits is an oscillator, in particular a voltage-controlled oscillator (VCO). VCOs are used in a range of different circuits, for instance for clock generation or timing control as part of PLLs (phase-locked loops) or FLLs (frequency-locked loops) or the like. VCOs have also been used as part of an analogue-to-digital converter (ADC) arrangement, and some VCO based ADCs can have the advantage of being small in circuit area, although non-linearity can be a significant issue.

One known type of VCO is a ring oscillator, which comprises a plurality of delay elements, typically an odd number of inverters, configured in a ring arrangement. In a conventional implementation in silicon, each inverter may comprise a PMOS transistor and NMOS transistor connected in series between an input voltage and ground, with each inverter being driven by the previous inverter in the ring. The propagation delay associated with each inverter thus has a dependence on the drive strength of the preceding inverter, which in turn has a dependence on the input voltage, and thus varying the input voltage varies the propagation delay and hence the oscillation frequency.

As noted above, however, it is not generally practical to implement p-channel devices in GaN.

### SUMMARY

Embodiments of the present disclosure relate to oscillator circuits, in particular to voltage-controlled-oscillator circuits, which mitigate at least some of these issues.

According to an aspect of the disclosure there is provided a voltage-controlled oscillator circuit, the circuit comprising an input node for receiving an input control voltage and an odd plurality of delay elements connected in a ring arrangement. Each delay element is connected between first and second defined voltages and comprises a depletion mode high-electron mobility transistor connected between the first defined voltage and an output of the delay element and an enhancement mode high-electron mobility transistor connected between the output of the delay element and the second defined voltage. A gate of the depletion mode high-electron mobility transistor is driven by the input control voltage and a gate of the enhancement mode high-electron mobility transistor is driven by the output of a preceding delay element.

In some implementations, the input control voltage may be configured to be variable in a voltage range that operates the depletion mode high-electron mobility transistor in a linear regime. In some implementations, the first defined voltage may be a supply voltage VDD and the second defined voltage may be ground. The input control voltage may be configured to be greater than the sum of the first defined voltage and a threshold voltage of the depletion mode high-electron mobility transistor.

In some implementations, the voltage-controlled oscillator circuit may further comprise a reset switch for selectively connecting an output of one of the delay elements to a reset voltage.

In some implementations, at least one of the delay elements may comprise a variable capacitance connected to the gate of the enhancement mode high-electron mobility transistor.

In some implementations, the voltage-controlled oscillator may be configured so that a number of active delay elements in the ring can be selectively controlled. The voltage-controlled oscillator may be configured so that the number of active delay elements in the ring can be selectively controlled based on at least one of a power consumption mode and a desired precision.

In some implementations, the circuit may be formed in gallium nitride.

Also provided is a signal processing circuit comprising a first voltage-controlled oscillator circuit according to any of the embodiments disclosed herein, where the first voltage-controlled oscillator circuit is configured to receive a first input signal as its input control voltage and to output a first oscillation signal. An arbiter may be configured to receive the first oscillation signal and a second oscillation signal and to determine whether the first oscillation signal has a phase and/or frequency lead compared to the second oscillation signal and output a corresponding output signal. The signal processing circuit may further comprise a second voltage-controlled oscillator circuit according to any of the embodiments discussed herein, where the second voltage-controlled oscillator circuit is configured to receive a second input signal as its input control voltage and to output the second oscillation signal.

In some implementations, the arbiter may comprise a D-type flip-flop configured to receive the first oscillation signal as a data input and the second oscillation signal as a clock input. In some implementations, the arbiter may comprise a phase-and-frequency detector. The output signal may be a pulse-width-modulation signal indicative of the extent of variation in frequency between the first oscillation signal and the second oscillation signal. In some implementations, the arbiter may comprise a counter configured to generate respective counts of a number of edges of the first and second oscillation signals in a defined time window.

The signal processing circuit may be operable in a calibration mode in which the first input signal corresponds to a known voltage input.

The signal processing circuit may be configured as a comparator.

Also provided is an amplifier circuit comprising a first voltage-controlled oscillator circuit according to any of the embodiments disclosed herein, the first voltage-controlled oscillator circuit being configured to receive a first input signal as its input control voltage and to output a first oscillation signal, and a second voltage-controlled oscillator circuit according to any of the embodiments disclosed herein, the second voltage-controlled oscillator circuit being configured to receive a second input signal as its input control voltage and to output a second oscillation signal. An arbiter may be configured to receive the first oscillation signal and the second oscillation signal and to output a corresponding amplifier output signal indicative of the extent of any frequency difference between the first and second oscillation signals. A feedback path may be configured to provide a feedback signal derived from the amplifier output signal to the input of one of the first and second voltage-controlled oscillator as negative feedback.

In some implementations, the feedback path may be configured to provide a feedback signal derived from the amplifier output signal to the input of one of the first voltage-controlled oscillator and the feedback path may comprise a feedback impedance comprising at least one feedback resistor. The first voltage-controlled oscillator may receive the first input signal via a first input path comprising an input impedance comprising at least one input resistor. In some implementations, the first input signal may be a first pulse-width-modulation signal and the amplifier output signal is a second pulse-width-modulation signal. The amplifier circuit may further comprise at least one capacitor connected to the input of the first voltage-controlled oscillator to form a high-pass filter for filtering a carrier frequency of the first and second pulse-width-modulation signal. The second input signal may be a voltage reference signal.

Also provided is a Hall sensor circuit comprising: a hall sensor configured to be biased by a bias voltage applied to first and second biasing electrodes and to generate first and second sense voltages at respective first and second read-out electrodes; a first voltage-controlled oscillator circuit according to any of the embodiments discussed herein, the first voltage-controlled oscillator circuit being configured to receive the first sense voltage as its input control voltage and to output a first oscillation signal; and a second voltage-controlled oscillator circuit according to any of the embodiments discussed herein, the second voltage-controlled oscillator circuit being configured to receive the second sense voltage as its input control voltage and to output a second oscillation signal. The Hall sensor circuit may further comprise an arbiter configured to receive the first oscillation signal and a second oscillation signal and to output a corresponding amplifier output signal indicative of the extent of any frequency difference between the first and second oscillation signals.

In another aspect, there is provided a voltage-controlled oscillator circuit formed in a compound semiconductor, the circuit comprising: an input configured to receive an input control voltage; an odd plurality of delay elements connected in a ring arrangement; each delay element connected between first and second defined voltages and comprising: a first transistor configured as a variable resistance controlled by the input control voltage; and a second transistor configured as a voltage pull-down transistor controlled by a preceding delay element.

A signal processing circuit may comprise a first voltage-controlled oscillator circuit as according to any of the embodiments described herein, the first voltage-controlled oscillator circuit being configured to receive a first input signal as its input control voltage and to output a first oscillation signal; and a second voltage-controlled oscillator circuit accordingly to any of the embodiments described herein, the second voltage-controlled oscillator circuit being configured to receive a second input signal as its input control voltage and to output a second oscillation signal. An arbiter may be configured to receive the first oscillation signal and a second oscillation signal and to output a corresponding output signal indicative of the extent of any frequency difference between the first and second oscillation signals.

In another aspect there is provided an amplifier circuit configured to receive a first input pulse-width-modulation signal and output an output pulse-width-modulation signal. The amplifier circuit comprises a first voltage-controlled oscillator configured to receive the first input pulse-width-modulation signal and generate a corresponding first oscillation signal; a phase-and-frequency detector configured to receive the first oscillation signal and a reference oscillation signal and output the output pulse-width-modulation signal based on any frequency difference between the first oscillation signal and the reference oscillation signal; a feedback path from the output of the phase-and-frequency detector to an input of the first voltage-controlled oscillator, and a filter coupled to the input of the voltage-controlled oscillator to filter a carrier component of the first input pulse-width-modulation signal and the output pulse-width-modulation signal.

In another aspect there is provided a voltage-controlled oscillator circuit, the circuit comprising: an input node for receiving an input control voltage; and a plurality of delay elements connected in a ring arrangement; wherein the input control voltage is applied to each of the plurality of delay elements; and wherein the input node presents as a high-impedance input.

It should be noted that, unless expressly indicated to the contrary herein or otherwise clearly incompatible, then any feature described herein may be implemented in combination with any one or more other described features.

### BRIEF DESCRIPTION OF DRAWINGS

For a better understanding of examples of the present disclosure, and to show more clearly how the examples may be carried into effect, reference will now be made, by way of example only, to the following drawings in which:

FIG. 1 illustrates a known voltage-controlled oscillator formed from PMOS and NMOS elements in a ring arrangement;

FIG. 2 illustrates one example of a voltage-controlled oscillator that uses only n-channel devices;

FIG. 3 illustrates an example of a voltage-controlled oscillator that uses only n-channel devices and which has a high-input impedance;

FIG. 4 illustrates a comparator formed using voltage-controlled oscillators;

FIG. 5 illustrates an amplifier circuit with op-amp functionality formed from voltage-controlled oscillators;

FIG. 6 illustrates another amplifier circuit with op-amp functionality formed from voltage-controlled oscillators operable with PWM input and output signals;

FIG. 7 illustrates a Hall sensor arrangement with voltage-controlled oscillator read-out; and

FIG. 8 illustrates tuning of the load capacitance of a delay element.

### DETAILED DESCRIPTION

The description below sets forth example embodiments according to this disclosure. Further example embodiments and implementations will be apparent to those having ordinary skill in the art. Further, those having ordinary skill in the art will recognize that various equivalent techniques may be applied in lieu of, or in conjunction with, the embodiments discussed below, and all such equivalents should be deemed as being encompassed by the present disclosure.

Embodiments of the disclosure relate to oscillator circuits, in particular to voltage-controlled oscillator (VCO) circuits that are suitable for implementation in a compound semiconductor material such as Gallium Nitride (GaN).

As noted above, VCOs have been implemented as ring oscillators in conventional silicon circuits.

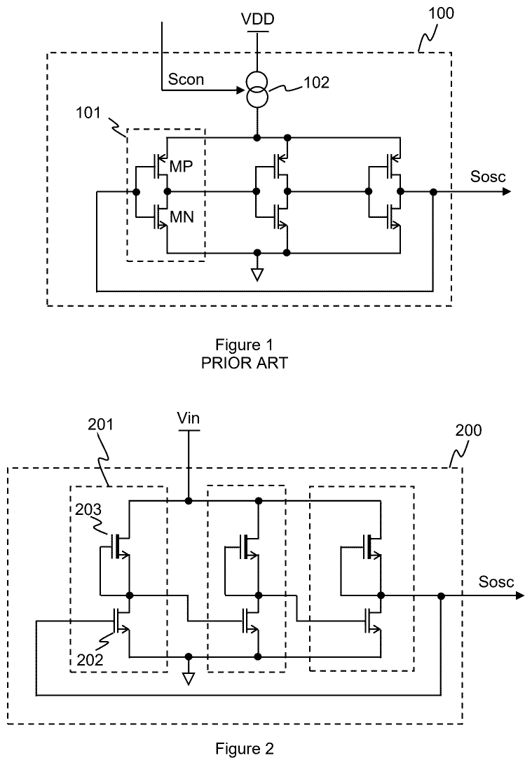

FIG. 1 illustrates one known example of a basic form of ring oscillator 100 as may be implemented by CMOS devices in a conventional (single element) silicon circuit. The ring oscillator 100 in this example comprises an odd plurality of inverters 101, each of which comprises a PMOS transistor MP in series with an NMOS transistor MN between high-side and low-side voltages, e.g. a supply voltage VDD and ground. The output of each inverter 101, which is taken from the midpoint of the series connected transistors MP and MN, provides the gate drive input for the next inverter. The PMOS and NMOS transistors act in a complementary manner to drive the output of the inverter 101 high or low depending on the input to the inverter 101. An output is tapped from an appropriate part of the ring arrangement to provide the output signal Sosc from the ring oscillator 100.

The output frequency of the ring oscillator 100, i.e. the frequency of the output signal Sosc, depends on the number of inverters 101 in the ring arrangement and the individual propagation delay associated with each inverter. The propagation delay of each inverter 101, i.e. the delay between a change in the input and a corresponding change in the output of the inverter 101, depends on the properties of the transistors and the drive strength of the inverters, i.e. how quickly the output of one inverter can charge or discharge the gate capacitances of the PMOS and NMOS device of the next inverter to drive the output voltage high or low as appropriate.

To provide a controllably variable output frequency, the drive strength of the inverters 101 may be controllably varied in use so as to vary the propagation delay of the inverters. FIG. 1 illustrates an example where a received control signal Scon, for instance a control voltage for a VCO implementation, is used to control a current source arrangement 102 that defines the strength of the drive signal which is output from each inverter, but it will be understood that other arrangements are possible. In general, though, the received control signal Scon varies the propagation delay of the inverters 101, and consequently the output frequency of the VCO 100.

Ring oscillators such as described with reference to FIG. 1 may be used for a range of different applications, such as generation of clock signals.

However, for circuits implemented in GaN, difficulties in implementing p-channel device means that a ring oscillator such as illustrated in FIG. 1 would not be practical.

A ring oscillator could be implemented in GaN by replacing the p-channel devices MP of the circuit of FIG. 1 with a resistance, so that each inverter has a resistive pull-up and an actively controlled pull-down. FIG. 2 illustrates one example of a ring oscillator 200 as could be implemented in GaN. The oscillator 200 comprises an odd number of inverting delay elements 201 arranged in a ring arrangement in a similar manner as the oscillator of FIG. 1.

Each of the delay elements 201 comprises a pull-up arrangement and a pull-down arrangement for driving the output high or low depending on the state of the input. In the example of FIG. 2, the pull-down arrangement comprises a transistor 202, implemented as a switching device connected between the output for the delay element 201 and the low-side voltage, e.g. ground, with its control terminal, e.g. gate, driven by the input for the delay element 201. The pull-down transistor 202 may be an enhancement mode high electron mobility transistor (HEMT), or more generally an n-channel transistor.

The pull-up arrangement may comprise a resistance. Whilst a passive component, such as a resistor, could be used, in the example of FIG. 2 the pull-up arrangement comprises a depletion mode HEMT 203 with a connected gate and source, although it will be understood that other arrangements are possible.

The use of a pull-up arrangement, such as implemented by depletion mode HEMT 203 or a passive resistance, for the delay elements 201 means that the delay elements 201 can be implemented without the need for any p-channel transistors, which means that such delay elements can be readily implemented in compound semiconductor materials such as GaN.

In use, when the pull-down transistor 202 is on, i.e. conducting, the output of the delay element 201 is pulled down to the low side voltage, whereas when the pull-down transistor 202 is off, i.e. non-conducting, the output of the delay element 201 is pulled high. The pull-up provided by the depletion mode HEMT 203 is thus an inherent or passive pull-up that occurs when the pull-down transistor 202 is non conducting.

In the example of FIG. 2, each delay element is connected between an input voltage Vin and the low-side voltage, which is ground in this example. The propagation delay of each delay element 201 depends on the drive strength of the preceding delay element. The drive strength of the output from each delay element 201 depends on the input voltage, and the properties of the pull-down transistor 202 and depletion mode HEMT 203. Varying the input voltage Vin will thus vary the driver strength of each delay element 201, and hence the propagation delay associated with each delay element and thus the oscillation period/frequency. The input voltage Vin is thus a control voltage for the VCO.

However, in the arrangement illustrated in FIG. 2, the input voltage Vin effectively provides the drive current for each of the delay elements 201, and this voltage is effectively applied to nodes of the delay elements 201 which are relatively low impedance. This can result in current being drawn from the source of the input voltage Vin, i.e. loading of this source, which can be undesirable.

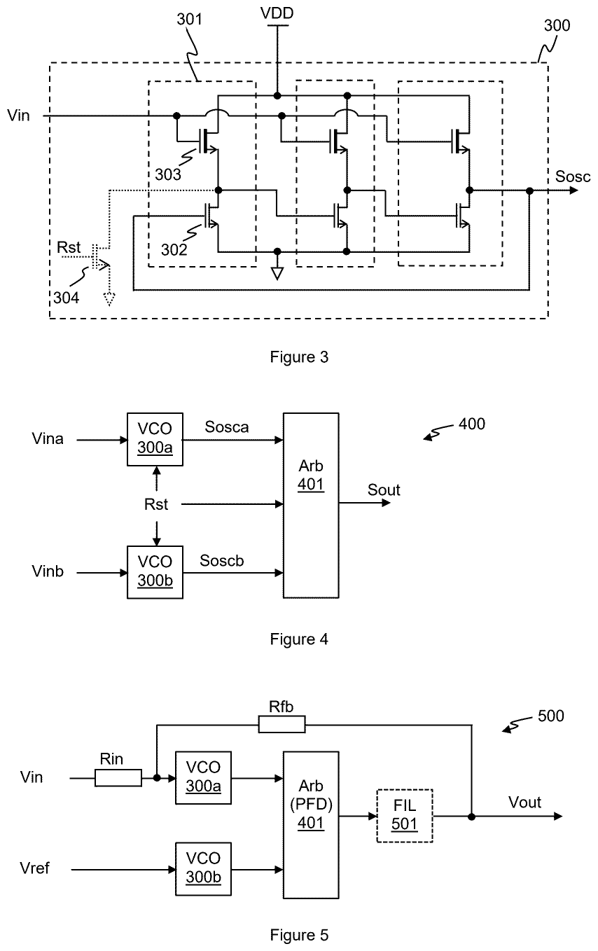

FIG. 3 illustrates an example of a ring-oscillator 300 which is suitable for use in material systems such as GaN and which avoids this problem. The ring-oscillator 300 again comprises a plurality of delay elements 301, which may for example comprise an odd number of inverters, connected in a ring arrangement in a similar manner as discussed with reference to FIGS. 1 and 2. FIG. 3 illustrates three delay stages, but it will be understood that this is just an example and different number of delay stages could be used.

In the example of FIG. 3, each delay element 301 is connected between two defined voltages, in this example a supply voltage VDD and ground. The supply voltage VDD may, in some applications, be a substantially fixed voltage that does not substantially vary in use, other than possibly some minor fluctuations due to power supply noise or the like. In some cases, the oscillator circuit may be operable in different modes or regimes, and the supply voltage could be different in the different operating mode or regime, e.g. depending whether the supply voltage is provided from a battery supply or some other power source such as mains or USB connection, but within a given operating mode or regime the supply voltage may not be deliberately varied, i.e. the supply voltage VDD is not used as the control voltage for the VCO.

Each delay element 301 again comprise a pull-up arrangement and a pull-down arrangement. The pull-down arrangement comprises a transistor 302, which may be implemented as an enhancement mode HEMT transistor 302 whose gate is driven by the output of the preceding delay element 301 in the ring.

The pull-up arrangement is provided by a transistor 303, which may be implemented as a depletion mode HEMT transistor 303 whose gate is driven by the input voltage Vin, i.e. by the control voltage. The input voltage Vin is thus applied to the gates of the depletion mode HEMT transistors 303 of the delay elements 301 and, as these gates are effectively high-impedance, in use, there is no significant loading of the source of the input voltage Vin. The input node for the VCO is thus a high-impedance input node, i.e. there is no substantial current flow via the input node with the input voltage Vin applied.

In use, the depletion mode HEMT 303 effectively acts as a tuneable resistor, whose resistance depends on the input voltage Vin applied to its gate. The enhancement mode HEMT 302 acts as a digital switch controlled by the logic signal from the previous delay element in the ring. In similar manner as discussed with reference to FIG. 2, each delay element 301 in the ring charges and discharges its output node through the current flowing from the depletion mode HEMT 303, thereby introducing a delay and oscillation occurs due to the cumulative delay across an odd number of such stages arranged in a feedback loop.

When the enhancement mode HEMT 302 turns on, it pulls the output node low, allowing the load capacitance at that node, i.e. the gate capacitance of the next delay element and any associated capacitance, to discharge. When it turns off, the depletion mode HEMT 303 pulls the output node high, charging the load capacitance. The rate at which this charging occurs determines the propagation delay, and hence the frequency of oscillation. The charging current is limited by the resistance of the depletion mode HEMT 303, which is controlled by the control voltage Vin. Thus, varying Vin adjusts the delay per element 301, and hence the oscillation frequency.

To achieve predictable and monotonic control of frequency, it is desirable for the depletion mode HEMT 303 to operate in the linear (ohmic) region, where its drain current behaves linearly with respect to the drain-source voltage. This ensures that the resistance of the depletion mode HEMT 303 is well-defined and smoothly tuneable with the control voltage Vin.

As will be understood by one skilled in the art, the condition for the depletion mode HEMT 303 to operate in the linear regime is that its drain-source voltage Vds is less than Vgs - Vt, where Vgs is the gate-source voltage and Vt is the threshold voltage.

It can be shown that the gate voltage of the depletion mode HEMT 303 should therefore preferably exceed the supply voltage VDD by, at least, the (negative) threshold voltage Vt, so as to operate in the linear regime, i.e. the control voltage Vin should be greater than VDD+Vt. For example, if VDD was equal to 5V and the threshold voltage is −3V, then Vin should be greater than 2V.

This may result in some consideration being given to any level shifters or other analog circuit used for generating the relevant input voltage Vin. It may also influence the choice of supply voltage VDD and/or the threshold engineering for the depletion mode HEMT 303. For instance, implementing the depletion mode HEMT 303 to have a more negative threshold can potentially widen the control range and reduce the required input voltage Vin.

Using a depletion mode HEMT 303 in series with an enhancement mode HEMT 302 in series thus provides a compact and effective architecture for building high-speed VCOs. The depletion mode HEMT 303, acting as a tuneable resistor, governs the charging current for the output node, and hence the frequency of oscillation. Significantly, for a range of input voltages the VCO 300 exhibits very linear voltage to frequency conversion. It also has a high input impedance and, unlike the example of FIG. 2, does not load the control source. This arrangement also has the advantage that each of the delay elements 301 will always slew between the two defined voltages, e.g. VDD and ground.

A VCO 300 such as described with reference to FIG. 3 can be used to generate an oscillating output signal Sosc with a controlled oscillation period and hence frequency. Such a VCO could, for example, be used as part of some timing or clocking device such as a FLL or PLL or the like. In some implementations, the VCO 300 could be implemented as part of a VCO based ADC.

As the input impedance for the VCO 300 is high, the VCO 300 can be used as a building block in other functional circuits.

For example, VCOs according to the embodiments described herein could be used to implement a comparator. A VCO-based comparator decides which of two voltages is larger by converting voltage to time/phase rather than comparing amplitudes directly.

FIG. 4 illustrates one example of a comparator 400 implemented using VCOs.

FIG. 4 illustrates that a first VCO 300a, which may be a VCO such as described with reference to FIG. 3, is configured to receive a first input voltage Vina. A second VCO 300b, which may also be a VCO such as described with reference to FIG. 3, is configured to receive a second input voltage Vinb. The first and second VCOs generate respective first and second oscillation signals Sosca and Soscb, each oscillation signal at a respective frequency equal to f0+Vin*KVCO, where f0 is the base frequency for the relevant VCO and KVCO is the relevant conversion gain, in terms of the amount of variation in frequency with variation of the relevant input voltage. For a direct comparison of the two input voltages, the first and second VCO may have the same substantially the same base frequency and conversion gains as one another and the first and second VCOs 300a and 300b may be substantially identical to one another. The first and second VCOs 300a and 300b may also located relatively physically close to one another, so as to be at substantially the same temperature in use. However, in some implementations at least some gain or offset could be introduced into the comparison, if desired, by implementing the first and second oscillators to have a different base frequency and/or different conversion gains to one another.

An arbiter 401 receives both the first and second oscillations signals Sosca and Soscb and effectively determines which of the first and second oscillators runs ahead of the other and outputs a corresponding output signal Sout.

Note, in some implementations, the second input voltage Vinb could be a reference voltage which is supplied to the second VCO 300b so that the second oscillation signal Soscb is a reference oscillation signal at a reference frequency. In some implementations, such a reference frequency signal, e.g. a clock signal or the like, may be available anyway, in which case the second VCO 300b could be omitted and the reference frequency signal supplied directly to the arbiter 401 as the second oscillation signal Soscb.

There are various ways in which a suitable arbiter 401 could be implemented. In some implementations the arbiter could be a D-type flip-flop or the like, implemented using n-channel devices so as to be suitable for implementation in GaN. In this case, the first oscillation signal Sosca may effectively provide a data input for the D-type flip-flop and the second oscillation signal Soscb may effectively provide a clock input. If the first oscillation signal Sosca has a higher frequency than the second oscillation signal Soscb, then the edges of the first oscillation signal Sosca can trigger the flip-flop to output a logic 1 output at the sample times defined by the edges of the second oscillation signal Soscb, whereas if the first oscillation signal Sosca has a lower frequency than the second oscillation signal Soscb, the output will be a logic 0. In this example the output signal Sout from the comparator could be a high/low logic signal.

Alternatively, the arbiter 401 could be implemented as PFD (phase-and-frequency detector), implemented using n-channel devices so as to be suitable for implementation in GaN. A PFD, as will be understood by one skilled in the art, is a known component of various circuits, such as FLLs and the like. A PFD can receive two oscillating signals and generate an output which is proportional to the frequency difference between the two signals—for instance as a PWM (pulse density modulation) signal—together with an indication of the polarity of the difference. A PFD can thus provide not only an indication of whether the frequency of the first oscillation signal Sosca is higher or lower than the second oscillation signal Soscb, but can also provide an indication of the extent of the difference, which is thus an indication of the extent of the difference between the input voltages Vina and Vinb. In this case the output signal Sout can be a PWM signal indicative of the difference between the input voltage Vina and Vinb.

For integration with the VCOs 300a and 300b as part of a GaN integrated circuit, the arbiter 401 may be implemented without using any p-channel devices. The arbiter 401 may, for instance be implemented using resistor-transistor logic (RTL) and n-channel devices. One skilled in the art would ready understand how a flip-flop or PFD could be implemented using RTL, e.g. a flip-flop can be constructed using two n-channel transistors or HEMTs in respective circuit branches, the gate of each transistor being connected to a respective input and also to an output of the other circuit branch via appropriate resistances.

In some implementations the arbiter 401 could be implemented as an edge counter to count the number of edges in at least the first oscillation signal Sosca a fixed time window. In the example where the second oscillation signal Soscb has a fixed reference frequency, the second oscillation signal Soscb may be used to define the time window. However, where the second oscillation signal Soscb does not have a stable reference frequency, some other stable reference clock (CLK) could be used to define the time windows with edge counts of both the first and second oscillation signals Sosca and Soscb being performed and the difference in count value determined to provide either a simple logic output or an indication of the extent of the frequency difference.

In any of these implementations of arbiter 401, the decision of the comparator may be formed by the integrated phase of (at least) the first oscillation signal Sosca over time. This integration over time is beneficial in that any offset and thermal noise is averaged, with the consequential performance benefits. In some implementations, the duration of the time window for making the comparator decision may be controllably variable, this can provide a trade off between speed and precision.

For the comparator 400 of the example of FIG. 4, it is advantageous to ensure that each of the VCOs 300a and 300b start in a defined output state, i.e. start with a desired phase state. FIG. 4 illustrates that the first and second VCOs 300a and 300b may thus be reset to a desired phase state by a suitable reset signal Rst. Referring back to FIG. 3, the VCO 300 may thus, in some implementations, comprise a switch 304 which may be turned on by the reset signal Rst to drive one node of the VCO 300 to a defined voltage so as to set a phase state for the VCO. Referring back to FIG. 4, the reset signal may also be supplied to the arbiter 401 to reset the arbiter 401 for synchronism with the first and second VCOs 300a and 300b. In general, the reset switch 304 could be connected to any of the nodes of the VCO 300, but it may be advantageous for the reset to be applied to the node of the VCO 300 which is furthest away from the output so as to maximise the propagation delay between reset of the VCO to the desired phase state and a change of state of at the oscillator output, i.e. to maximise the number of delay elements that need to switch before there is an edge in the oscillator output signal Sosc. Thus, if the oscillator output signal Sosc is seen as being output from a last delay element of the ring arrangement, the reset may be applied to the output of the first delay element.

The comparator 400 may, in some implementations, be operable in calibration mode, to calibrate for any drift in base frequency or conversion gain, e.g. due to PVT (process voltage or temperature variations). The calibration mode implemented may depend on the implementation. For instance, where the arbiter 401 comprises a counter, count values could be compared to expected values when a known voltage is applied as Vina. Additionally or alternatively, when used as a comparator, the same voltage could be applied to both inputs, i.e. so Vina=Vinb to determine a count value that corresponds to no difference between the inputs.

In some implementations, the comparator 400 may effectively make a single comparator decision, i.e. the VCOs 300a and 300b could be reset to the same phase state and then operated to determine which of the first and second oscillation signals Sosca and Soscb exhibits an edge first. In some implementations, however, the arbiter 401 could be configured to run multiple comparison operations and combine the results into a single decision.

For instance, the VCOs 300a and 300b could be repeatedly reset to the same phase state and then operated to determine which of the first and second oscillation signals Sosca and Soscb exhibits an edge first, over a certain number of operations or within a defined time window. The outcome of each individual comparison operation could be recorded or stored and then combined into a final outcome, e.g. based on which of the first and second oscillation signals Sosca and Soscb exhibited an edge the majority of times.

In some instances, the arbiter 401 could be implemented as a counter which generates a count value of the number of the edges in each of the first and second oscillation signals Sosca and Soscb, but which only generates an output when the difference in count exceeds a certain threshold, which may be a threshold above a zero count value.

As noted above, two counters could instead provide count values of the number of respective edges in the first and second oscillation signals Sosca and Soscb over a defined time window that corresponds to a relatively large number of oscillation periods, and the highest count value used to provide the output of the comparator 400.

As noted, above, the comparator 400 can be implemented with a PFD or similar as the arbiter 401 to provide an output signal which is PWM signal indicative of a voltage difference between the input voltages. The PWM output signal effectively encodes an output voltage Vout, as the average voltage over one or more PWM switching cycles, where the output voltage Vout depends on the difference between Vina and Vinb. In a similar manner, VCOs according to embodiments of the present disclosure can be used to provide a circuit with the functionality of an op-amp.

FIG. 5 illustrates one example of a VCO amplifier circuit 500 with op-amp functionality, in which similar components to those discussed previously are identified by the same reference numerals.

The VCO amplifier circuit 500 again comprises a first VCO 300a configured to receive a first input voltage Vin, in this case via input resistor Rin, and a second VCO 300b configured to receive a second input voltage, which in this example is a reference voltage, Vref. In a similar manner as discussed above with reference to FIG. 4, the first and second VCOs 300a and 300b each generate respective oscillation signals which are input to arbiter 401. The arbiter 401 in this example is a PFD which, as noted above, generates a PWM output signal indicative of the voltage difference between Vin and Vref.

In some implementations, the PWM output from the arbiter 401 may be filtered by a suitable filter, such as a low-pass filter, to provide an analog output voltage Vout. However, in some applications it may be sufficient to provide the PWM output signal as a PWM representation of the output voltage Vout for use by some downstream circuitry or downstream filtering as desired.

The output from the arbiter 401 is fed back, via feedback resistor Rfb, to the voltage at the input to the first VCO 300a. This feedback signal may be tapped from before or after the filter 501, if present. For this example of FIG. 5, the PWM output from the PFD of the arbiter 401 is configured to vary oppositely with the input voltage Vin. That is, as the input voltage Vin rises above the reference voltage Vref, the duty-cycle of the PWM output signal (in terms of the proportion of the switching cycle spent at a higher voltage) will reduce and as the input voltage Vin drops below the reference voltage Vref, the duty-cycle of the PWM signal will increase. This means that the input voltage Vin can be seen as being applied to an inverting input of the VCO amplifier circuit 500 and the feedback is negative feedback. It will be understood that, in an alternative arrangement, the PWM output from the PFD may be configured to vary together with the input voltage Vin, which is akin to the input voltage being applied to a non-inverting input of the VCO amplifier circuit, but in that case the feedback may be applied to the reference voltage Vref to provide negative feedback.

It should be noted that in the example of FIG. 5, the input current due to the input voltage Vin applied to the input resistor Rin is equal to the feedback current via feedback resistor Rfb so the current at the input of the VCO 300a sums to zero, which is a property of op-amp functionality.

In the example of FIG. 5, the feedback operates to minimise any error between the input voltages to the first and second VCOs 300a and 300b in a similar manner to a conventional op-amp. Like a conventional op-amp, the closed-loop transfer function can be set by the relative values of the feedback resistor Rfb and input resistor Rin. The open-loop gain of the VCO amplifier circuit derives from the phase integration provided by the VCO and any gain provided by the PFD, and can be very large, similar to a conventional op-amp.

It will be understood that the example of FIG. 5 illustrates a relatively simple feedback arrangement with just a feedback resistor Rf, but other, more complex feedback networks involving one or more resistors and/or capacitors could be implemented in some applications.

The VCO amplifier circuit 500 of FIG. 5 thus can receive an analog input voltage Vin and output an analog output voltage Vout after appropriate filtering or, as mentioned, can output a PWM output signal representing the output voltage Vout.

In some applications, it may be desirable for the input signal encoding the input voltage Vin to also be a PWM signal. In some applications it may be advantageous to be able to apply signal processing to PWM signals without a need to convert to and from analog signals.

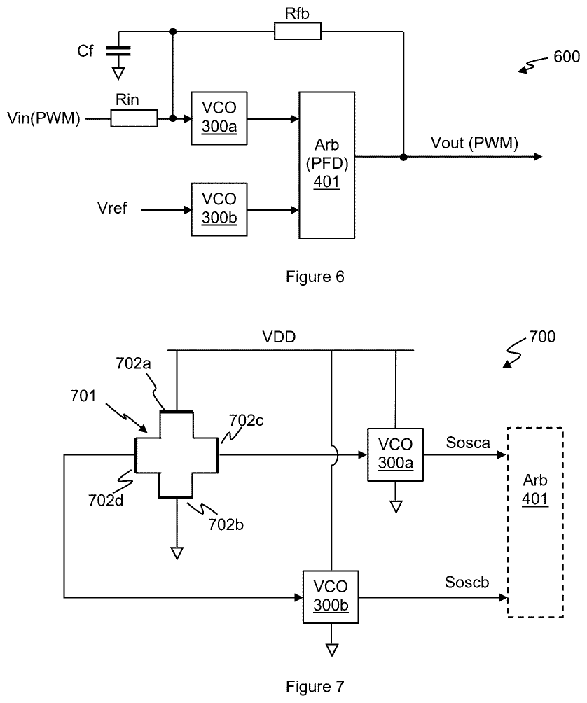

FIG. 6 illustrates an example of a VCO amplifier circuit 600 with op-amp functionality that can be used to receive a PWM input signal and provide a PWM output signal, in which similar components are identified by similar reference numerals.

The VCO amplifier circuit 600 is similar to the VCO amplifier circuit 500 discussed with reference to FIG. 5, but in this example the input voltage Vin may be received as a PWM input voltage signal and the output voltage Vout may be provided as PWM output voltage signal Vout(PWM). In the example of FIG. 6, the output voltage Vout(PWM) is thus used to provide a feedback signal to be combined with the PWM input to the first VCO 300a. In this case, mixing could occur due the PWM carrier frequency in each of the PWM signals, resulting in unwanted folding down of noise components into the signal band of interest. To mitigate this issue, the example of FIG. 6 includes a capacitance Cf coupled to the feedback node. This capacitor, together with the input and feedback resistors Rin and Rfb, effectively provides a high-pass filter function at this node to shunt the power at the carrier frequency to ground.

The cutoff frequency Fc for this filter can be given by 1/(2π·Reff·Cf), where Reff is the parallel resistance of Rin and Rfb. The value of the capacitance Cf should be chosen so this cutoff frequency Fc is greater than the signal band of interest but below the PWM carrier frequency.

Note this idea of providing a VCO based amplifier with op-amp functionality that can process PWM input signals represents a novel aspect of this disclosure which is applicable to any materials system and which would, for example, be suitable for CMOS devices in a conventional single element silicon integrated circuit.

In general, however, embodiments of the present disclosure relate to VCO circuits that can be implemented without the use of p-channel devices and which are suitable for use in compound semiconductor material systems such as GaN. Embodiments of the present disclosure thus can provide VCOs that can be implemented in GaN. Such VCo may be highly linear and can have the advantages of GaN of fast operation. The VCOs can be relatively small in circuit area and/or low power. VCO circuits according to embodiments of the present disclosure can also be used as building blocks for other functional circuits that can be implemented in GaN, for instance to provide a comparator or an amplifier with op-amp functionality.

In some embodiments, one or more VCOs according to an embodiment could be provided as part of a read-out arrangement for some sensing element, which may, for instance, comprise a Hall sensor. As will be understood by one skilled in the art, a Hall sensor is a known sensor for sensing a magnetic field based on the Hall effect.

FIG. 7 illustrates one example of sensing arrangement 700 including a Hall sensor 701 with VCO based read-out. Typical Hall sensors comprise a planar material, with a first pair of electrodes 702a and 702b on opposite sides of the planar material to one another on a first axis and a second pair of electrodes 702c and 702d on opposite sides of the planar material to one another on a second axis, which may typically be substantially orthogonal to the first axis. The Hall sensor may be configured for use in a voltage mode, in which a known voltage may be applied across the first pairs of electrodes 702a and 702b, e.g. the first and second electrodes may be connected to VDD and ground respectively. This generates a DC bias current within the Hall sensor that can lead to a potential difference between the electrodes 702c and 702d that depends on the strength of any applied magnetic field, that is the voltage at the electrode 702c may be equal to (VDD+Vhall)/2 and the voltage at the electrode 702d may be equal to (VDD−Vhall)/2, where Vhall is the Hall voltage due to magnetic field.

For VCO based read-out, the respective voltages at the electrodes 702c and 702d may be applied to first and second VCOs 300a and 300b in a similar manner as discussed with reference to FIG. 4. As the inputs to the first and second VCOs 300a and 300b are high impedance this, advantageously, does not result in any loading of the Hall sensor 701. The first and second VCOs 300a and 300b generate respective first and second oscillation signals Sosca and Soscb with oscillation periods/frequencies that depend on the applied voltages. The frequency difference between the first and second oscillation signals Sosca and Soscb thus depends on the Hall voltage Vhall, and hence on the applied magnetic field strength.

Note that the sensor arrangement 700 of FIG. 7 uses two VCOs 300a and 300b to provide read-out of the voltage difference between the electrodes 702c and 702d. In theory, one VCO could be used for readout of the voltage at just one electrode, and the resulting oscillation signal compared to which would be expected at the nominal voltage of VDD/2, however, in practice, the arrangement of FIG. 7 is preferred for performance reasons.

This effectively provide a digital indication of the Hall voltage and the sensor arrangement 700 can thus be seen as a digital Hall sensor which does not require a separate ADC.

The frequency difference between these two oscillation signals can be decoded in a number of different ways but, in some embodiments, the sensor apparatus may comprise an arbiter 401 such as PFD in a similar manner as discussed above to generate a sensor output indicative of the frequency difference and hence the Hall voltage. In some implementations the first and second oscillation signals Sosca and Soscb may be supplied to one or more counters, e.g. the arbiter 401 may comprise a counter block. In some cases, the number of oscillations in each of the first and second oscillation signals Sosca and Soscb may be counted in a fixed time window defined by a reference clock and a difference in count value determined, or the number of oscillations of the first and second oscillation signals Sosca and Soscb in a period defined by the other of the first and second oscillation signals Sosca and Soscb may be counted.

In some implementations the Hall sensor 701 may be implemented in a compound semiconductor material, such as GaN and may be integrated with the VCOs 300a and 300b and arbiter 401 (if present). This provide a magnetic sensing capability that can be integrated as part of a circuit in a compound semiconductor material system, such as GaN, for magnetic sensing, which could, for example, be used to provide some current sensing functionality.

Note that the supply voltage VDD used to bias the Hall sensor 701 may also be used as the voltage supply for the first and second VCOs 300a and 300b. As noted above, the voltage at the electrode 702c or 702d, which provides the control voltage for the relevant VCO 300a or 300b, will be equal to VDD/2±Vhall/2. This can mean that control voltage for each of the first and second VCOs 300a and 300b is within the correct range for linear operation of the depletion mode HEMTs 303 as discussed above. For instance, if VDD is 5V and the threshold voltage Vt it−3V, the control voltage should be greater than 2V. In this case, the voltage at the electrode 702c or 702d will be equal to 2.5V±Vhall, which allows a potential difference of up to 1V between the electrodes 702c and 702d for linear operation of the VCOs. If, instead, VDD were 3V (and the threshold voltage were −3V) the VCOs would inherently operate in the linear regime.

In some applications, it may be advantageous to be able to tune the operation of the oscillator, e.g. to vary the base frequency of the VCO and/or the power consumption of the VCO. This may, for instance, allow for tuning of process variations and/or where the VCO is used to provide some signal processing function, provide a trade off between speed and power or precision.

In general, the frequency of oscillation depends on the propagation delay of each element and the number N of elements. The propagation delay for each element is a function of the rise time to charge the output node when the pull-down enhancement mode HEMT 302 is off and the fall-time to discharge the output node when the pull-down enhancement mode HEMT 303 is on. The rise time has a dependence on the variable resistance of the depletion mode HEMT 302 as discussed previously, but also depends on the supply voltage VDD and the load capacitance C_{L}. The fall time also has a dependence on the load capacitance C_{L}. As noted above, it may be advantageous to maintain a fixed supply voltage VDD.

One way to vary the frequency of oscillation would thus be to vary the resistance of the pull-up arrangement. Clearly varying the input voltage Vin applied to the VCO, and hence the gates of the depletion-mode HEMTs 303 will vary the resistance of the depletion-mode HEMTs 303, and hence the resistance of the pull-up arrangement and the oscillation frequency as discussed above, and thus operating with different ranges for the input voltage Vin could provide different operating ranges of frequency. However, in at least some applications it may be preferable to tune the frequency independently of the input voltage Vin. In this case some variable resistance could be included as part of the pull-up arrangement. In some cases, the pull-up arrangement of each of the delay elements could comprise a plurality of depletion mode HEMTs 303 connected in parallel with one another. One or more of the depletion mode HEMTs could be selectively used to provide the variable resistance, i.e. the input voltage could be selective applied to the gates of a selected one or more the parallel depletion-mode HEMTs, with the other HEMTs being maintained in an off-state. Varying the number of HEMTs used can vary the overall resistance and/or at least some of the parallel HEMTs may have different characteristics to one another, e.g. different channel lengths, to provide different resistance characteristics. Increasing the resistance of the pull-up arrangement of the delay elements will extend the rise time for each delay element and hence increase the oscillation period/reduce the oscillation frequency, which can save power in terms of switching losses.

The base frequency of oscillation could therefore be adjusted by changing one or both of the load capacitance C_{L} and the number of (active) delay elements of the oscillator. Note varying the load capacitance C_{L} would vary both the rise time and the fall time of the relevant delay element and if the load capacitance of each of the delay elements was varied in the same way, the resulting variation in oscillation period would be linear with the variation in load capacitance. The overall oscillation period also depends on the number of delay elements and thus the period also varies linearly with the number of delay elements.

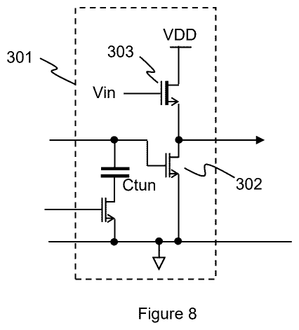

The load capacitance (for at least one delay element) could be selected varied in various ways, for example FIG. 8 illustrates that at least tuning capacitance Ctun could be selective connected in parallel with the gate capacitance of the delay stage to vary the overall load capacitance C_{L}. Varying the load capacitance can tune the oscillation period, and hence oscillation frequency, of the oscillator with a resulting impact on sensitivity, but varying the load capacitance in this way does not, itself, provide any significant power saving.

As will be understood by one skilled in the art, the power consumption P of each delay element, in terms of switching losses, is given by P=f·C_{L}·VDD² where f is the oscillation frequency. The power consumption thus has a dependence on the load capacitance C_{L} and VDD. However, the power consumption also has a dependence on frequency, and as noted, the frequency also varies with C_{L} and VDD. The oscillation period is linear with load capacitance C_{L} and thus reducing the load capacitance would reduce the oscillation period, with a consequent reduction in sensitivity. This would also reduce the switching loss associate with each switching operation (as C_{L} is halved), but the reduction in oscillation period results in an increased switching frequency and thus there is a consequent increase in the number of switching operations and the power consumption due to switching losses essentially remains the same. It will thus be understood that varying the load capacitance provides a way to tune the oscillation period/frequency of the oscillator without substantially varying the switching losses.

Varying the number N of delay elements which are enabled would also vary the sensitivity of the oscillator and reducing the number of active delay elements would reduce sensitivity, but again this would increase the frequency, and each delay element would thus switch more often and the overall number of switching operations would stay the same, so again without any significant change in switching losses.

However, varying the number of enabled delay element, i.e. enabling/disabling some delay elements, can vary some conduction losses associated with operation of the oscillator. It will be appreciated that during operation, each delay element will swap between the high output state, where the enhancement mode HEMT 302 is off, and a low output state in which the transistor enhancement mode HEMT 302 is on. In the low output state, when the enhancement mode HEMT 302 is on, current will flow from the VDD supply to ground via the depletion mode HEMT 303 (with a value based on VDD and the resistance of the depletion mode HEMT 303), with associated power loss. In operation, about half of the delay elements will be in the low output state at any time and thus these conduction losses scale according to the number of enabled delay elements in the oscillator.

Thus, by controllably varying the number of delay elements which are active as part of the VCO, a trade-off between power and sensitivity can be achieved—although it will be understood that there should always be a plurality of active delay elements and the number of active delay elements should be odd, so the minimum number of active delay elements in use will be three.

As noted above, varying the load capacitance can also be used to tune the oscillation period and hence frequency, and, in some embodiments, some tuning of the load capacitance may be applied together with a variation in the number of active delay elements. For instance, if the number of active delay elements is reduced to save power, the load capacitance could be varied to offset at least some of the change in oscillation frequency that would otherwise result.

It should be understood—especially by those having ordinary skill in the art with the benefit of this disclosure—that the various operations described herein, particularly in connection with the figures, may be implemented by other circuitry or other hardware components. The order in which each operation of a given method is performed may be changed, and various elements of the systems illustrated herein may be added, reordered, combined, omitted, modified, etc. It is intended that this disclosure embrace all such modifications and changes and, accordingly, the above description should be regarded in an illustrative rather than a restrictive sense.

Similarly, although this disclosure makes reference to specific embodiments, certain modifications and changes can be made to those embodiments without departing from the scope and coverage of this disclosure. Moreover, any benefits, advantages, or solutions to problems that are described herein with regard to specific embodiments are not intended to be construed as a critical, required, or essential feature or element.

Further embodiments, likewise, with the benefit of this disclosure, will be apparent to those having ordinary skill in the art, and such embodiments should be deemed as being encompassed herein.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

1. A voltage-controlled oscillator circuit, the circuit comprising:
an input node for receiving an input control voltage; and
an odd plurality of delay elements connected in a ring arrangement;
each delay element connected between first and second defined voltages and comprising:
a depletion mode high-electron mobility transistor connected between the first defined voltage and an output of the delay element, wherein a gate of the depletion mode high-electron mobility transistor is driven by the input control voltage; and
an enhancement mode high-electron mobility transistor connected between the output of the delay element and the second defined voltage, wherein a gate of the enhancement mode high-electron mobility transistor is driven by the output of a preceding delay element.

2. The voltage-controlled oscillator circuit of claim 1 wherein the input control voltage is configured to be variable in a voltage range that operates the depletion mode high-electron mobility transistor in a linear regime.

3. The voltage-controlled oscillator circuit of claim 1 wherein the first defined voltage is a supply voltage VDD and the second defined voltage is ground.

4. The voltage-controlled oscillator circuit of claim 1 wherein the input control voltage is configured to be greater than the sum of the first defined voltage and a threshold voltage of the depletion mode high-electron mobility transistor.

5. The voltage-controlled oscillator circuit of claim 1 further comprising a reset switch for selectively connecting an output of one of the delay elements to a reset voltage.

6. The voltage-controlled oscillator circuit of claim 1 wherein at least one of the delay elements comprises a variable capacitance connected to the gate of the enhancement mode high-electron mobility transistor.

7. The voltage-controlled oscillator circuit of claim 1 wherein the voltage-controlled oscillator is configured so that a number of active delay elements in the ring can be selectively controlled.

8. The voltage-controlled oscillator circuit of claim 7 wherein the voltage-controlled oscillator is configured so that the number of active delay elements in the ring can be selectively controlled based on at least one of a power consumption mode and a desired precision.

9. The voltage-controlled oscillator circuit of claim 7 wherein the circuit is formed in Gallium Nitride.

10. A signal processing circuit comprising:
a first voltage-controlled oscillator circuit as claimed in claim 1, the first voltage-controlled oscillator circuit being configured to receive a first input signal as its input control voltage and to output a first oscillation signal; and
an arbiter configured to receive the first oscillation signal and a second oscillation signal and to determine whether the first oscillation signal has a phase and/or frequency lead compared to the second oscillation signal and output a corresponding output signal.

11. The signal processing circuit of claim 10 further comprising a second voltage-controlled oscillator circuit, the second voltage-controlled oscillator circuit being configured to receive a second input signal as its input control voltage and to output the second oscillation signal.

12. The signal processing circuit of claim 10 wherein the arbiter comprises a D-type flip-flop configured to receive the first oscillation signal as a data input and the second oscillation signal as a clock input.

13. The signal processing circuit of claim 10 wherein the arbiter comprises a phase-and-frequency detector.

14. The signal processing circuit of claim 13 wherein the output signal is a pulse-width-modulation signal indicative of the extent of variation in frequency between the first oscillation signal and the second oscillation signal.

15. The signal processing circuit of claim 10 wherein the arbiter comprises a counter configured to generate respective counts of a number of edges of the first and second oscillation signals in a defined time window.

16. The signal processing circuit of claim 10 wherein the signal processing circuit is operable in a calibration mode in which the first input signal corresponds to a known voltage input.

17. The signal processing circuit of claim 10 wherein the signal processing circuit is configured as a comparator.

18. An amplifier circuit comprising a first voltage-controlled oscillator circuit and a second voltage-controlled oscillator circuit as claims in claim 1:
the first voltage-controlled oscillator circuit being configured to receive a first input signal as its input control voltage and to output a first oscillation signal; and
the second voltage-controlled oscillator circuit being configured to receive a second input signal as its input control voltage and to output a second oscillation signal; further comprising:
an arbiter configured to receive the first oscillation signal and the second oscillation signal and to output a corresponding amplifier output signal indicative of the extent of any frequency difference between the first and second oscillation signals; and
a feedback path configured to provide a feedback signal derived from the amplifier output signal to the input of one of the first and second voltage-controlled oscillator as negative feedback.

19. The amplifier circuit of claim 18 wherein the feedback path is configured to provide a feedback signal derived from the amplifier output signal to the input of one of the first voltage-controlled oscillator and wherein the feedback path comprises a feedback impedance comprising at least one feedback resistor and wherein the first voltage-controlled oscillator receives the first input signal via a first input path comprising an input impedance comprising at least one input resistor.

20. The amplifier circuit of claim 19 wherein the first input signal is a first pulse-width-modulation signal and the amplifier output signal is a second pulse-width-modulation signal.

21. The amplifier circuit of claim 20 further comprising at least one capacitor connected to the input of the first voltage-controlled oscillator to form a high-pass filter for filtering a carrier frequency of the first and second pulse-width-modulation signal.

22. The amplifier circuit of claim 21 wherein the second input signal is a voltage reference signal.

23. A Hall sensor circuit comprising a first voltage-controlled oscillator circuit and a second voltage-controlled oscillator circuit as claimed in claim 1:
a hall sensor configured to be biased by a bias voltage applied to first and second biasing electrodes and to generate first and second sense voltages at respective first and second read-out electrodes;
the first voltage-controlled oscillator circuit being configured to receive the first sense voltage as its input control voltage and to output a first oscillation signal; and
the second voltage-controlled oscillator circuit being configured to receive the second sense voltage as its input control voltage and to output a second oscillation signal.

24. The Hall sensor circuit of claim 23 further comprising an arbiter configured to receive the first oscillation signal and a second oscillation signal and to output a corresponding amplifier output signal indicative of the extent of any frequency difference between the first and second oscillation signals.

25. A voltage-controlled oscillator circuit formed in a compound semiconductor, the circuit comprising:
an input configured to receive an input control voltage;
an odd plurality of delay elements connected in a ring arrangement;
each delay element connected between first and second defined voltages and comprising:
a first transistor configured as a variable resistance controlled by the input control voltage; and
a second transistor configured as a voltage pull-down transistor controlled by a preceding delay element.

26. A signal processing circuit comprising a first voltage-controlled oscillator circuit and a second voltage-controlled oscillator circuit as claims in claim 25:
the first voltage-controlled oscillator circuit being configured to receive a first input signal as its input control voltage and to output a first oscillation signal; and
the second voltage-controlled oscillator circuit being configured to receive a second input signal as its input control voltage and to output a second oscillation signal;
further comprising an arbiter configured to receive the first oscillation signal and a second oscillation signal and to output a corresponding output signal indicative of the extent of any frequency difference between the first and second oscillation signals.

27. An amplifier circuit configured to receive a first input pulse-width-modulation signal and output an output pulse-width-modulation signal, the amplifier circuit comprising:
a first voltage-controlled oscillator configured to receive the first input pulse-width-modulation signal and generate a corresponding first oscillation signal;
a phase-and-frequency detector configured to receive the first oscillation signal and a reference oscillation signal and output the output pulse-width-modulation signal based on any frequency difference between the first oscillation signal and the reference oscillation signal;
a feedback path from the output of the phase-and-frequency detector to an input of the first voltage-controlled oscillator, and
a filter coupled to the input of the voltage-controlled oscillator to filter a carrier component of the first input pulse-width-modulation signal and the output pulse-width-modulation signal.

28. A voltage-controlled oscillator circuit, the circuit comprising:
an input node for receiving an input control voltage; and
a plurality of delay elements connected in a ring arrangement;
wherein the input control voltage is applied to each of the plurality of delay elements; and
wherein the input node presents as a high-impedance input.
